(19) United States
(12) Patent Application Publication
(10) Pub. No.: US 2023/0148362 A1
(43) Pub. Date: May 11, 2023

(54) APPARATUS FOR DIAGNOSING BATTERY AND METHOD THEREOF

(71) Applicants: Hyundai Motor Company, Seoul (KR); Kia Corporation, Seoul (KR); Hyundai Sungwoo Solite, Seoul (KR)

(72) Inventors: Ki Seon RYU, Seoul (KR); Sang Jin Lee, Hwaseong-Si (KR); Jun Hyeong Park, Daejeon (KR); Sung Hoon Cha, Gyeongju-Si (KR); Jung Eui Ko, Gwangju (KR)

(73) Assignees: Hyundai Motor Company, Seoul (KR); Kia Corporation, Seoul (KR); Hyundai Sungwoo Solite, Seoul (KR)

(21) Appl. No.: 17/939,682

(22) Filed: Sep. 7, 2022

(30) Foreign Application Priority Data
Nov. 10, 2021 (KR) 10-2021-0154216

(51) Int. Cl. G01R 31/367; G01R 31/00

(52) U.S. Cl. CPC G01R 31/367; G01R 31/007

(57) ABSTRACT

A battery diagnostic apparatus includes a storage, a battery state manager, and a battery diagnostic device. The storage includes battery state history data including periodic battery charge state information. The battery state manager stores the battery state history data in the storage and retrieves the stored battery state history data. The battery diagnostic device is configured to determine a usage pattern depth of discharge in a state of charge based on the battery state history data, and predicts a remaining life of a battery based on the battery state history data and the usage pattern depth of discharge.

### CROSS-REFERENCE TO RELATED APPLICATION

The present application claims priority to Korean Patent Application No. 10-2021-0154216, filed on Nov. 10, 2021, the entire contents of which is incorporated herein for all purposes by this reference.

### BACKGROUND OF THE PRESENT DISCLOSURE

### Field of the Present Disclosure

The present disclosure relates to an apparatus and method for diagnosing a battery, and more particularly, relates to an apparatus and method for diagnosing a battery of an electric vehicle or a hydrogen electric vehicle.

### Description of Related art

Because a vehicle battery is a consumable part, it needs to be replaced. It is advisable to replace the battery before a battery life is exhausted and reaches a non-functional condition. However, it is not easy to predict the battery life or occurrence of defects of the battery because the battery life varies depending on various external factors.

The conventional method for diagnosing a battery mounted in a vehicle of an internal combustion engine type is mainly performed based on a change in a battery impedance or an open circuit voltage (OCV).

However, because a battery mounted in an electric vehicle or a hydrogen electric vehicle has a very different usage environment from a battery mounted in an internal combustion engine vehicle, the cause of the failure is different from that of the battery mounted in the internal combustion engine vehicle. Therefore, the accuracy is very low for diagnosing the lifespan or the possibility of failure of a battery mounted in an electric vehicle or a hydrogen electric vehicle using the conventional battery diagnostic method.

Accordingly, a new method for diagnosing a battery mounted in an electric vehicle or a hydrogen electric vehicle is being sought.

The information included in this Background of the present disclosure section is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an apparatus and method for diagnosing a battery which is difficult to diagnose by a method for diagnosing a battery of an internal combustion engine vehicle.

Another exemplary embodiment of the present disclosure is to provide an apparatus and method for diagnosing a battery configured for determining not only the life of the battery, but also a battery having a high probability of occurrence of a defect.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, a battery diagnostic apparatus includes storage, a battery state manager, and a battery diagnostic device. The storage contains battery state history data including periodic battery charge state information. The battery state manager stores the battery state history data in the storage and retrieves the stored battery state history data. The battery diagnostic device is configured to determine a usage pattern depth of discharge in a state of charge based on the battery state history data, and predicts a remaining life of a battery based on the battery state history data and the usage pattern depth of discharge.

In an exemplary embodiment of the present disclosure, the battery state manager may manage the battery state history data to include information on distribution ratios for each section of the state of charge.

In an exemplary embodiment of the present disclosure, the battery diagnostic device may determine a sum of the distribution ratios for each section of the state of charge, may determine state of charge sections in which the sum of the distribution ratios is equal to or greater than a threshold ratio as usage patterns, may select the largest state of charge among the usage patterns as a maximum state of charge, selects a smallest state of charge among the usage patterns as a minimum state of charge, and may determine a difference between the maximum state of charge and the minimum state of charge to obtain the usage pattern depth of discharge.

In an exemplary embodiment of the present disclosure, the battery diagnostic device may predict the remaining life of the battery to be longer in proportion to a size of the usage pattern depth of discharge.

In an exemplary embodiment of the present disclosure, the battery diagnostic device may predict the remaining life of the battery to be longer in proportion to a size of the minimum state of charge.

In an exemplary embodiment of the present disclosure, the battery diagnostic device may determine the remaining life of the battery based on Equation 1 below,

$$remaining life of battery ( \% ) = \frac{\begin{matrix}Turn of number [ TON ] - \\ total discharge amount of battery / \\ battery capacity\end{matrix}}{Turn of number [ TON ]} \times 100 \qquad [ Equation 1 ]$$

In an exemplary embodiment of the present disclosure, the battery diagnostic device may allow the battery to be discharged by driving an electric component receiving a voltage from the battery, may determine a discharge time for which the voltage of the battery reaches a threshold voltage due to the discharge of the battery, and may determine that as the discharge time is shorter, a possibility of battery failure is higher.

In an exemplary embodiment of the present disclosure, the battery diagnostic device may allow the battery to be discharged by driving the electric component in a state in which an operation of a low voltage DC-DC converter reducing a high voltage and providing a voltage to the battery is stopped.

In an exemplary embodiment of the present disclosure, the battery diagnostic device may allow the battery to be discharged by driving the electric component based on the state of charge of the battery of 50% or more than 50%.

In an exemplary embodiment of the present disclosure, the battery diagnostic device may notify a user of a recommendation to replace the battery based on a fact that the discharge time is less than a threshold time.

According to an aspect of the present disclosure, a battery diagnostic method includes retrieving battery state history data including periodic battery charge state information, determining a usage pattern depth of discharge of a state of charge based on the battery state history data, and predicting a remaining life of a battery based on the battery state history data and the usage pattern depth of discharge.

In an exemplary embodiment of the present disclosure, the retrieving of the battery state history data may include extracting distribution ratios of the state of charge for each section from the battery state history data.

In an exemplary embodiment of the present disclosure, the determining of the usage pattern depth of discharge may include determining a sum of the distribution ratios for each section of the state of charge, determining state of charge sections in which the sum of the distribution ratios is equal to or greater than a threshold ratio as usage patterns, selecting the largest state of charge among the usage patterns as a maximum state of charge, selecting a smallest state of charge among the usage patterns as a minimum state of charge, and determining a difference between the maximum state of charge and the minimum state of charge to obtain the usage pattern depth of discharge.

In an exemplary embodiment of the present disclosure, the predicting of the remaining life of the battery may include predicting the remaining life of the battery to be longer in proportion to a size of the usage pattern depth of discharge.

In an exemplary embodiment of the present disclosure, the predicting of the remaining life of the battery may include predicting the remaining life of the battery to be longer in proportion to a size of the minimum state of charge.

In an exemplary embodiment of the present disclosure, the predicting of the remaining life of the battery includes determining the remaining life of the battery based on Equation 1 below,

$$remaining life of battery ( \% ) = \frac{\begin{matrix}Turn of number [ TON ] - \\ total discharge amount of battery / \\ battery capacity\end{matrix}}{Turn of number [ TON ]} \times 100 \qquad [ Equation 1 ]$$

In an exemplary embodiment of the present disclosure, the battery diagnostic method may further include, after the predicting of the remaining life of the battery,

allowing the battery to be discharged by driving an electric component receiving a voltage from the battery, determining a discharge time for which the voltage of the battery reaches a threshold voltage due to the discharge of the battery, and determining that as the discharge time is shorter, a possibility of battery failure is higher.

In an exemplary embodiment of the present disclosure, the allowing of the battery to be discharged by driving the electric component may further include stopping an operation of an LDC that reduces a high voltage and provides a voltage to the battery.

In an exemplary embodiment of the present disclosure, the allowing of the battery to be discharged by driving the electric component may be performed based on confirming that the state of charge of the battery is 50% or more than 50%.

In an exemplary embodiment of the present disclosure, the battery diagnostic method may further include notifying a user of a recommendation to replace the battery based on a fact that the discharge time is less than a threshold time.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a block diagram illustrating a configuration of an electric vehicle including a battery diagnostic apparatus of an electric vehicle, according to an exemplary embodiment of the present disclosure;

FIG. 2 is a flowchart for describing a battery diagnostic method according to an exemplary embodiment of the present disclosure;

FIG. 3 is a flowchart for describing an exemplary embodiment of determining a usage pattern depth of discharge according to an exemplary embodiment of the present disclosure;

FIG. 4 is a flowchart for describing an exemplary embodiment of predicting a remaining life of a battery;

FIG. 5 is a diagram illustrating experimental results of turn of number of battery obtained depending on an SOC;

FIG. 6 is a flowchart for describing a method of determining a battery discharge characteristic;

FIG. 7 is a diagram for describing a degree of voltage drop when a battery is discharged according to a degree of aging of a battery;

FIG. 8 is a flowchart for describing a battery diagnostic management method according to an exemplary embodiment of the present disclosure; and

FIG. 9 is a diagram illustrating a computing system according to an exemplary embodiment of the present disclosure.

It may be understood that the appended drawings are not necessarily to scale, presenting a somewhat simplified representation of various features illustrative of the basic principles of the present disclosure. The specific design features of the present disclosure as disclosed herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various exemplary embodiments of the present disclosure will be described in detail with reference to the drawings. In adding the reference numerals to the components of each drawing, it should be noted that the identical or equivalent component is designated by the identical numeral even when they are displayed on other drawings. Furthermore, in describing the exemplary embodiment of the present disclosure, a detailed description of the related known configuration or function will be omitted when it is determined that it interferes with the understanding of the exemplary embodiment of the present disclosure.

In describing the components of the exemplary embodiment according to an exemplary embodiment of the present disclosure, terms such as first, second, A, B, (a), (b), and the like may be used. These terms are merely intended to distinguish the components from other components, and the terms do not limit the nature, order or sequence of the components. Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as including a meaning which is consistent with their meaning in the context of the relevant art and will not be interpreted in an idealized or overly formal sense unless expressly so defined herein.

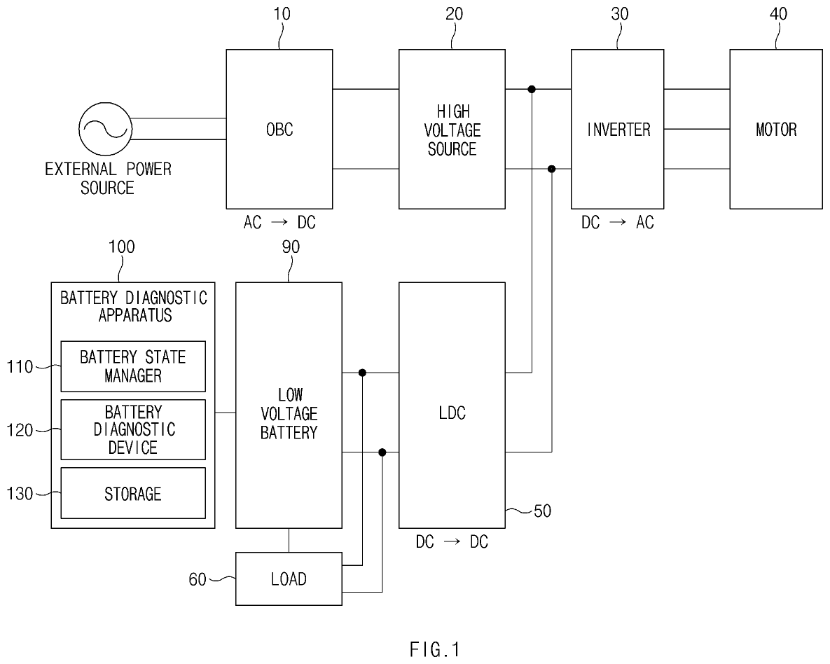

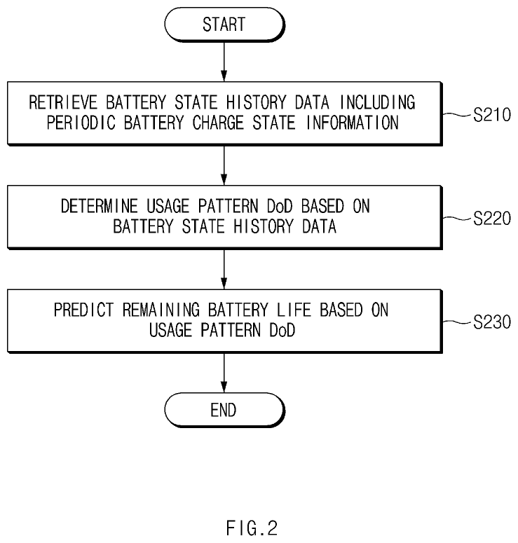

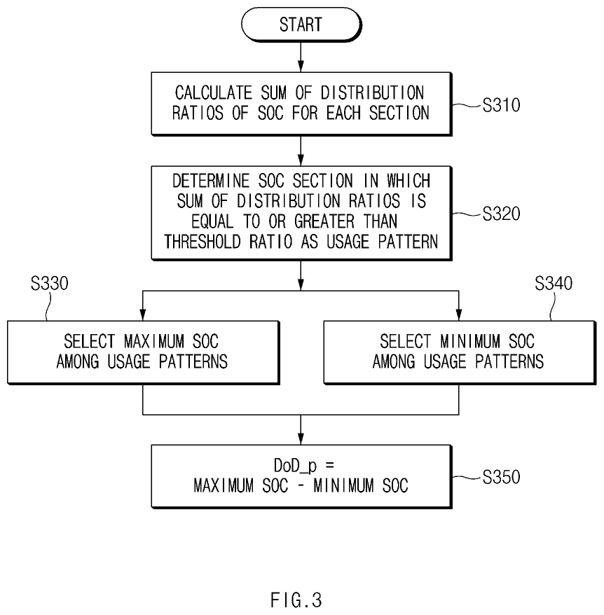

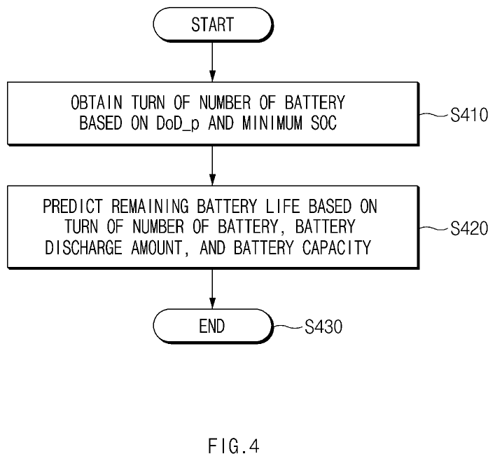

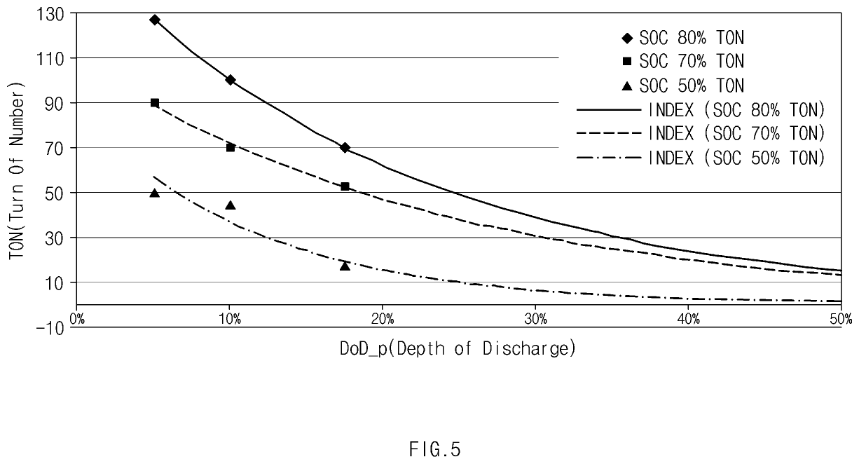

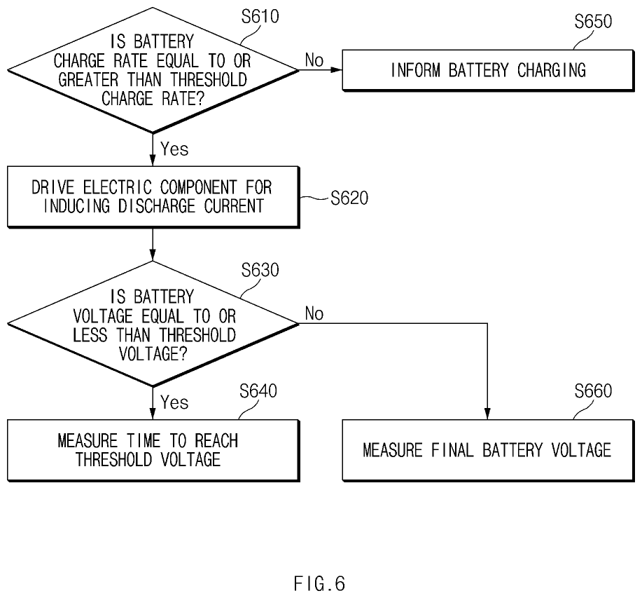

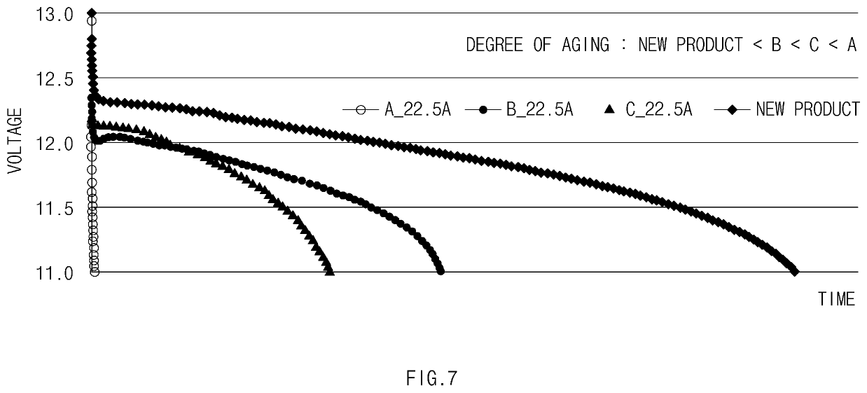

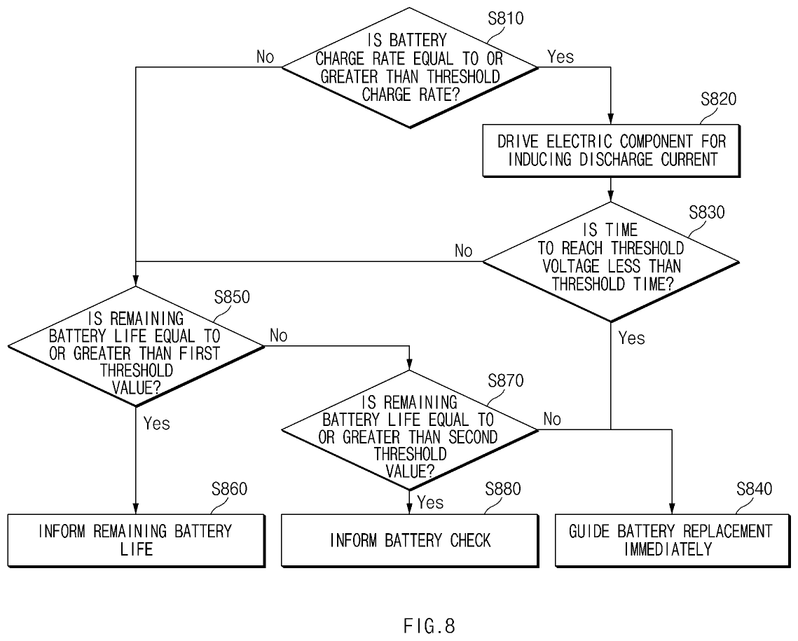

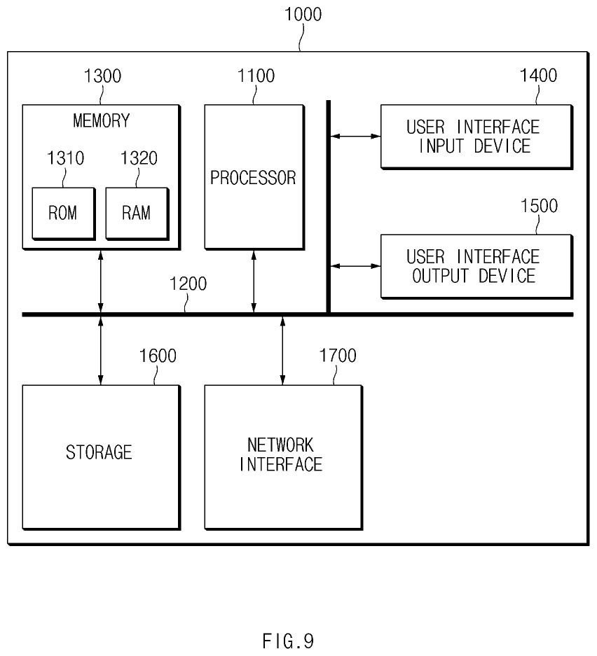

Hereinafter, various embodiments of the present disclosure will be described in detail with reference to FIG. 1, FIG. 2, FIG. 3, FIG. 4, FIG. 5, FIG. 6, FIG. 7, FIG. 8 and FIG. 9.

FIG. 1 is a block diagram illustrating a configuration of an electric vehicle including a battery diagnostic apparatus of an electric vehicle, according to an exemplary embodiment of the present disclosure.

Referring to FIG. 1, an electric vehicle including a battery diagnostic apparatus according to an exemplary embodiment of the present disclosure may include an on-board charger 10, a high voltage source 20, an inverter 30, a motor 40, and a low voltage DC-DC converter 50, a load 60, the low voltage battery 90, and a battery diagnostic apparatus 100.

The on-board charger (hereinafter referred to as OBC) 10 may boost AC power from an external power source and may convert it into direct current power DC.

The high voltage source 20 is charged by the OBC 10, and may provide power for driving the motor 40.

The inverter 30 may convert a DC voltage provided from the high voltage source 20 into an AC voltage, and may provide the converted AC voltage to the motor 40.

The low voltage DC-DC converter (LDC) 50 may charge the low voltage battery 90 by reducing the high voltage provided from the high voltage source 20. Furthermore, the low-voltage DC-DC converter 50 may provide a voltage for driving the loads 60 for the vehicle.

The loads 60 refer to a use of an electric component for the vehicle, and the exemplary embodiment of the present specification will be mainly described with reference to an exemplary embodiment in which the electric component of the vehicle utilizes 12V and a maximum charging voltage of the low voltage DC-DC converter 50 is 12V.

The low voltage battery 90 may provide power to electronic devices that are driven at 12V in the vehicle. Hereinafter, a battery referred to the exemplary embodiment of the present disclosure refers to the low voltage battery 90.

The battery diagnostic apparatus 100 may predict the remaining life of the battery based on battery state history data. Also, the battery diagnostic apparatus 100 may diagnose the possibility of a battery failure based on the battery state history data. To the present end, the battery diagnostic apparatus 100 may include a battery state manager 110, a battery diagnostic device 120, and storage 130.

The battery state manager 110 may include a detector that measures battery information such as a voltage, a current, an internal resistance, and a state of charge (SOC) value of the battery 90. The battery state manager 110 may store the distribution of the SOC in the storage 130 in units of a preset period. That is, the battery state manager 110 may store the SOC distribution rate for each section in units of the preset period in the storage 130, and the information stored in the storage 130 may be referred to as the battery state history data. Also, the battery state manager 110 may retrieve the battery state history data stored in the storage 130.

The battery diagnostic device 120 may predict the remaining life of the battery 90 based on the battery state history data. To the present end, the battery diagnostic apparatus 100 may determine the depth of discharge for each section of the state of charge, based on the battery state history data. Furthermore, the battery diagnostic apparatus 100 may predict the remaining life of the battery 90 based on the battery state history data and the depth of discharge for each section.

Also, after operation of predicting the remaining life the battery, the battery diagnostic device 120 may diagnose the possibility that the battery 90 may be defective. To the present end, the battery diagnostic device 120 may discharge the battery 90 and determine a discharge time until the voltage of the battery 90 reaches a threshold voltage. Furthermore, the battery diagnostic device 120 may determine that as the discharge time is shorter, there is a high probability that a failure of the battery 90 will occur, and may recommend replacing the battery 90 based on the fact that the discharge time is less than a threshold time.

The battery diagnostic device 120 may be a separate component, or may be included in the processor 1100 illustrated in FIG. 9 to be described later.

FIG. 2 is a flowchart illustrating a battery diagnostic method according to an exemplary embodiment of the present disclosure.

Referring to FIG. 2, a battery diagnostic method according to an exemplary embodiment of the present disclosure will be described as follows.

In a first step (S210), the battery state manager 110 may retrieve the battery state history data stored in the storage 130. [Table 1] and [Table 2] below are tables illustrating examples of the battery state history data provided in different vehicles.

TABLE 1

| | Holding time for each SOC section (0.5 minutes) | | | | | | | | |
|---|---|---|---|---|---|---|---|---|---|
| INDEX | ~30% | 31~40% | 41~50% | 51~60% | 61~70% | 71~80% | 81~90% | 91~100% | |
| (60 days) | (minute) | (minute) | (minute) | (minute) | (minute) | (minute) | (minute) | (minute) | Total |
| 1 | 0 | 0 | 0 | 47 | 3946 | 119038 | 46524 | 376 | 169931 |
| 2 | 0 | 0 | 0 | 0 | 0 | 96968 | 112966 | 14 | 169948 |
| 3 | 0 | 0 | 0 | 0 | 0 | 22618 | 131070 | 4514 | 158202 |
| 4 | 0 | 0 | 0 | 0 | 0 | 22876 | 131070 | 1320 | 155266 |
| 5 | 0 | 0 | 0 | 0 | 0 | 51842 | 118126 | 0 | 169968 |
| 6 | 0 | 0 | 0 | 0 | 2 | 120798 | 49176 | 0 | 169976 |
| Total | 0 | 0 | 0 | 47 | 3948 | 384140 | 588932 | 6224 | 993291 |
| Ratio | 0% | 0% | 0% | 0.0% | 0.4% | 39.7% | 59.3% | 0.6% | 100% |

TABLE 2

| | Holding time for each SOC section (0.5 minutes) | | | | | | | | |
|---|---|---|---|---|---|---|---|---|---|
| INDEX | ~30% | 31~40% | 41~50% | 51~60% | 61~70% | 71~80% | 81~90% | 91~100% | |
| (60 days) | (minute) | (minute) | (minute) | (minute) | (minute) | (minute) | (minute) | (minute) | Total |
| 1 | 38 | 2696 | 25902 | 15844 | 34838 | 44086 | 19158 | 11482 | 154044 |
| 2 | 0 | 0 | 5386 | 3576 | 31158 | 101602 | 24614 | 0 | 166336 |
| 3 | 0 | 0 | 0 | 50 | 28204 | 95944 | 38820 | 6862 | 169880 |
| 4 | 0 | 0 | 0 | 0 | 3602 | 93616 | 71844 | 776 | 169838 |
| 5 | 0 | 0 | 0 | 8453 | 32994 | 92694 | 27384 | 0 | 161525 |
| 6 | 0 | 0 | 0 | 0 | 59486 | 99476 | 10996 | 0 | 169958 |
| Total | 0 | 0 | 0 | 0 | 3264 | 102602 | 63212 | 128 | 991581 |
| Ratio | 0.0% | 0.3% | 3.2% | 2.8% | 19.2% | 53.2% | 19.4% | 1.9% | 100% |

Referring to [Table 1] and [Table 2], the battery state history data may include retention time information for each SOC section for each index.

The index may be a unit for storing retention time information for each SOC section, and may be counted, for example, in units of 60 days.

The retention time for each section may be set in units of 30 seconds, and when the index is 60, the sum of the retention times may be 60×24×60×2=172,800. However, due to a sensing error of the SOC value or an error occurring in a process of storing the SOC value in the storage 130, the sum of the retention times stored in each index may be 172,800 or less.

The SOC may be measured in units of 1% and may be divided into a plurality of preset sections. For example, an SOC value of 31% or more may be divided into sections in units of 10%, and an SOC value of 30% or less may be set as one section.

In a second step (S220), the battery diagnostic device 120 may determine the usage pattern depth of discharge based on the battery state history data provided from the battery state manager 110.

The use pattern depth of discharge may be determined based on the distribution ratio.

FIG. 3 is a flowchart for describing an exemplary embodiment of determining a usage pattern depth of discharge according to an exemplary embodiment of the present disclosure.

Referring to FIG. 3, the battery diagnostic device 120 may sum the distribution ratios of SOC for each section (S310). For example, as illustrated in [Table 1], the distribution ratio of the SOC 61 to 70% section may correspond to 3946 in index 1, may correspond to 0 in index 2 to index 5, and may correspond to 2 in index 6. Accordingly, the sum of the SOC distribution ratios for the 61 to 70% section may be determined as 3948, and the percentage for 993291, which is the total index, may be determined as 0.4%. As in the above description, the sum of the SOC distribution ratios for the 71 to 80% section may be determined as 39.7%, and the sum of the SOC distribution ratios for the 81 to 90% section may be determined as 59.3%.

In the case of battery history data for examples described in [Table 2], the sum of the SOC distribution ratios for the 61 to 70% section may be determined as 19.2%, and the sum of the SOC distribution ratios for the 71 to 80% section may be determined as 53.2%, and the sum of the SOC distribution ratios for the section 81 to 90% may be determined as 19.4%.

Next, the battery diagnostic device 120 may determine the SOC section in which the sum of the distribution ratios is equal to or greater than the threshold ratio as the usage pattern (S320). When the threshold ratio is set to 5%, the usage pattern in the cases described in [Table 1] may include a 71 to 80% SOC section and an 81 to 90% SOC section. Alternatively, the usage pattern in the cases described in [Table 2] may include a 61 to 70% SOC section, a 71 to 80% section, and an 81 to 90% SOC section.

The battery diagnostic device 120 may select the maximum SOC from among the usage patterns (S330). For example, in the cases described in [Table 1], the maximum SOC may be 90%, and in the cases described in [Table 2], the maximum SOC may be 90%.

The battery diagnostic device 120 may select the minimum SOC from among the usage patterns (S340). For example, in the cases described in [Table 1], the minimum SOC may be 71%, and in the cases described in [Table 2], the minimum SOC may be 61%.

The battery diagnostic device 120 may determine the difference between the maximum SOC and the minimum SOC to obtain the usage pattern depth of discharge DoD_p (S350). For example, in the cases illustrated in [Table 1], the usage pattern depth of discharge DoD_p may be determined as 19, and in the cases illustrated in [Table 2], the usage pattern depth of discharge DoD_p may be determined as 29.

In the third step S330, the battery diagnostic apparatus 100 may predict the remaining life of the battery 90 based on the battery state history data and the usage pattern depth of discharge DoD_p.

FIG. 4 is a flowchart for describing an exemplary embodiment of predicting a remaining life of a battery.

Referring to FIG. 4, the battery diagnostic device 120 may determine a turn of number (TON) of the battery based on the usage pattern depth of discharge DoD_p and the minimum SOC (S410). The turn of number (TON) of the battery may be obtained through a lookup table matching the usage pattern depth of discharge (DoD_p) and the minimum SOC as illustrated in [Table 3] below. As illustrated in FIG. 5, the lookup table of [Table 3] may be preset based on the test result of the turn of number (TON) of the battery obtained according to the SOC.

TABLE 3

| | | DOD_p | | | | | |
|---|---|---|---|---|---|---|---|
| Index | | 5% | 10% | 17.5% | 30% | 50% | 70% |
| minimum | 80% | 130 TON | 100 TON | 70 TON | 40 TON | . . . | . . . |
| SOC | 70% | 90 TON | 70 TON | 52 TON | 30 TON | . . . | . . . |
| | 50% | 50 TON | 40 TON | 15 TON | 5 TON | . . . | . . . |
| | 30% | . . . | . . . | . . . | . . . | . . . | . . . |
| | 10% | . . . | . . . | . . . | . . . | . . . | . . . |

Referring to FIG. 5 and [Table 3], it may be seen that the turn of number (TON) of the battery decreases in proportion to the usage pattern depth of discharge DoD_p. A low value of the usage pattern depth of discharge DoD_p may mean that charging is frequently performed in a state in which voltage consumption of the battery 90 is not large. That is, when charging and discharging are performed the same number of times, a low value of the usage pattern depth of discharge DoD_p may mean that the total discharge amount is smaller. Accordingly, the turn of number (TON) of the battery may be largely determined in inverse proportion to the size of the usage pattern depth of discharge DoD_p.

Furthermore, it may be seen that the turn of number (TON) of the battery increases in proportion to the minimum SOC. As the size of the minimum SOC is large, it may mean that the maximum amount of charge is used in a large charged state, and the performance of the battery is maintained well. Accordingly, the turn of number (TON) of the battery may be largely determined in proportion to the size of the minimum SOC.

The battery diagnostic device 120 may predict the remaining battery life based on the turn of number of the battery, the battery discharge amount, and the battery capacity (S420).

In an exemplary embodiment of the present disclosure, the battery diagnostic device 120 may predict the remaining battery life to be longer in proportion to the turn of number (TON) of the battery.

In another exemplary embodiment of the present disclosure, the battery diagnostic device 120 may predict the remaining battery life to be long in proportion to the size of the minimum SOC. The minimum SOC may be the SOC value of the smallest size among the usage patterns obtained based on step S340 of FIG. 3.

In another exemplary embodiment of the present disclosure, the battery diagnostic device 120 may predict the remaining battery life to be long in inverse proportion to the total discharge amount of the battery. The total discharge amount of the battery may be information stored in the storage 130 by the battery state manager 110. The total discharge amount of the battery may be a value obtained by accumulating the amount of current discharged due to the use of the battery because the first use of the battery.

In another exemplary embodiment of the present disclosure, the battery diagnostic device 120 may predict the remaining battery life to be long in inverse proportion to the battery capacity. The battery capacity is the amount of battery charge in the maximum charging state, and may be a value stored in the storage 130 by the battery state manager 110.

As another exemplary embodiment of the present disclosure, the battery diagnostic device 120 may determine the remaining battery life based on the following [Equation 1],

$$remaining life of battery ( \% ) = \frac{\begin{matrix}Turn of number [ TON ] - \\ total discharge amount of battery / \\ battery capacity\end{matrix}}{Turn of number [ TON ]} \times 100 \qquad [ Equation 1 ]$$

That is, the battery diagnostic device 120 may determine the remaining battery life based on Equation 1 in consideration of the turn of number (TON) of the battery, the battery capacity, and the total battery discharge amount. The battery diagnostic device 120 may determine the remaining battery life in a percentage method. The remaining life of ‘a’ (‘a’ is a number less than or equal to 100) % may refer to an expected lifespan that a period of ‘a’ % may be used compared to the remaining life of the initial battery.

The battery diagnostic apparatus 100 according to an exemplary embodiment of the present disclosure may determine the possibility of occurrence of a battery failure in addition to the remaining battery life. The step of determining the possibility of a battery failure is to determine a possibility of a battery failure occurring according to the degree of a voltage drop in a process of discharging the battery. Hereinafter, a battery discharge characteristic and a method of determining the possibility of occurrence of a battery failure based on the battery discharge characteristic will be referred to as follows.

FIG. 6 is a flowchart for describing a method of determining a battery discharge characteristic. The procedure for determining the battery discharge characteristic may correspond to a condition for determining the battery failure illustrated in FIG. 8, which will be described later.

Referring to FIG. 6, to determine the battery discharge characteristic, the battery diagnostic device 120 may determine whether the battery charge rate is equal to or greater than a threshold charge rate (S610). The threshold charge rate may be set within a range in which the battery may stably operate even when the battery is discharged for a certain period in a subsequent procedure. For example, the threshold charge rate may be set within 50%.

Based on that the battery charge rate is equal to or greater than the threshold charge rate, the battery diagnostic device 120 may drive the load 60 for inducing a discharge current (S620). To identify the battery discharge characteristics within a short time, the battery diagnostic device 120 may drive the load 60 driven by use of a high current. For example, the battery diagnostic device 120 may drive a blower motor of the air conditioning system to induce a discharge current of about 22.5 A.

After driving the load 60, the battery diagnostic device 120 may measure the battery voltage and determine whether the battery voltage is equal to or less than the threshold voltage (S630).

When the battery voltage is equal to or less than the threshold voltage, the battery diagnostic device 120 may measure the time at which the battery voltage reaches the threshold voltage (S640).

When the battery voltage does not drop below the threshold voltage, the battery diagnostic device 120 may measure the final battery voltage and may notify the measured voltage (S660). Maintaining a state in which the battery voltage exceeds the threshold voltage in a state in which the discharge current is induced is not a state of concern for the battery, so that the battery voltage due to discharge may be measured and managed.

In step S610, when the battery charge rate is less than the threshold charge rate, the battery diagnostic device 120 may inform the battery charging (S650). That is, the battery diagnostic device 120 may not proceed with determining the battery discharge characteristics until the battery is charged.

FIG. 7 is a diagram for describing a degree of voltage drop when a battery is discharged according to a degree of aging of a battery. The experiment illustrated in FIG. 7 illustrates that the voltage of the battery is measured while discharging the battery by driving a device connected to the battery. That is, FIG. 7 is a diagram for describing the characteristics of the battery being discharged by the step S620 of FIG. 6.

Referring to FIG. 7, discharge characteristics of a battery A, a battery B, a battery C, and a battery D are illustrated. The experimental results are illustrated based on the aging state in an order of the battery A, the battery B, the battery C, and the battery D.

Referring to FIG. 7, it may be seen that as the batteries age, a large voltage drop tends to occur during the same time period during the discharging process. In detail, it may be seen that a voltage drop rapidly occurs in a battery with a high degree of aging such as the battery A within a short time. In a battery with a high degree of aging, such as battery A, when the load 60 consuming a large amount of current is used, the battery voltage may be sharply lowered to cause an operation error of the loads 60. A battery diagnostic management method, which will be described later, may include a procedure of detecting a battery with a high degree of aging, such as the battery A, and determining the possibility of occurrence of a defect.

FIG. 8 is a flowchart for describing a battery diagnostic management method according to an exemplary embodiment of the present disclosure.

Referring to FIG. 8, the battery diagnostic management method according to an exemplary embodiment of the present disclosure will be referred to as follows.

In a first step (S810), the battery diagnostic device 120 may determine whether the battery charge rate is equal to or greater than a threshold charge rate. The first step (S810) may be the same procedure as that of step S610 illustrated in FIG. 6.

In the second step (S820), the battery diagnostic device 120 may drive the load 60 for inducing a discharge current based on that the battery charge rate is equal to or greater than the threshold charge rate. A second step (S820) may be the same procedure as that of step S620 illustrated in FIG. 6.

In a third step (S830), the battery diagnostic device 120 may count the time at which the battery voltage reaches the threshold voltage, and may determine whether the time at which the battery voltage reaches the threshold voltage is less than a threshold time. The threshold voltage may be the same voltage as the threshold voltage illustrated in FIG. 6. The threshold time may be determined based on the battery voltage drop due to the discharge current as illustrated in FIG. 7. The threshold time is for classifying a battery that needs to be replaced within a short time period due to severe aging, and may be set to, for example, 30 (s).

In a fourth step (S840), the battery diagnostic device 120 may provide a battery replacement guide based on the fact that the time to reach the threshold voltage is less than the threshold time. Accordingly, the battery A with a high degree of aging in FIG. 7 may be a target of battery replacement guidance through the fourth step (S840).

Based on that the time to reach the threshold voltage is equal to or greater than the threshold time, in a fifth step (S850), the battery diagnostic device 120 may identify the remaining battery life and determine whether the remaining battery life is equal to or greater than a first threshold value. The remaining life of the fifth step (S850) may be obtained through the procedures of S210 to S230 illustrated in FIG. 2. The first threshold value is a criterion for determining the degree to which the remaining life of the battery is stable, and may be set to, for example, 50%.

Based on that the remaining battery life is equal to or greater than the first threshold, in a sixth step (S860), the battery diagnostic device 120 may inform the remaining battery life.

Also, based on the fact that the remaining battery life is equal to or greater than a second threshold value in a seventh step (S870) and an eighth step (S880), the battery check may be guided. The second threshold value is the remaining life which may cause defects, and may be set to, for example, 20%. Accordingly, the procedure of guiding the battery check in the eighth step (S880) may be a step of guiding information that the battery remaining life is not long enough although the occurrence of a defect is not a concern.

In the seventh step (S870), when it is determined that the remaining battery life is less than the second threshold value, the battery replacement may be guided through the step S840. That is, in the seventh step (S870), the possibility of occurrence of a battery failure may be determined based on the remaining battery life.

FIG. 9 is a diagram illustrating a computing system according to an exemplary embodiment of the present disclosure.

Referring to FIG. 9, a computing system 1000 may include at least one processor 1100, a memory 1300, a user interface input device 1400, a user interface output device 1500, a storage 1600, and a network interface 1700, which are connected to each other via a bus 1200.

The processor 1100 may be a central processing unit (CPU) or a semiconductor device that processes instructions stored in the memory 1300 and/or the storage 1600. Each of the memory 1300 and the storage 1600 may include various types of volatile or nonvolatile storage media. For example, the memory 1300 may include a read only memory (ROM) and a random access memory (RAM).

Accordingly, the operations of the method or algorithm described in connection with the exemplary embodiments included in the specification may be directly implemented with a hardware module, a software module, or a combination of the hardware module and the software module, which is executed by the processor 1100. The software module may reside on a storage medium (i.e., the memory 1300 and/or the storage 1600) such as a random access memory (RAM), a flash memory, a read only memory (ROM), an erasable and programmable ROM (EPROM), an electrically EPROM (EEPROM), a register, a hard disk drive, a removable disc, or a compact disc-ROM (CD-ROM).

The storage medium may be coupled to the processor 1100. The processor 1100 may read out information from the storage medium and may write information in the storage medium. Alternatively, the storage medium may be integrated with the processor 1100. The processor and storage medium may be implemented with an application specific integrated circuit (ASIC). The ASIC may be provided in a user terminal. Alternatively, the processor and storage medium may be implemented with separate components in the user terminal.

According to an exemplary embodiment of the present disclosure, by use of a method different from the conventional method for diagnosing a battery for an internal combustion engine vehicle, it is possible to effectively diagnose a vehicle battery whose battery characteristics are changed due to frequent charging and discharging.

Furthermore, according to the exemplary embodiment of the present disclosure, because the battery is diagnosed based on the battery usage pattern, it is possible to effectively diagnose a battery including a defect due to the usage pattern, such as a battery of an electric vehicle or a hydrogen electric vehicle.

Furthermore, according to an exemplary embodiment of the present disclosure, it is possible to warn of a risk of a battery having a high probability of occurrence of a defect as well as the expected life of the battery.

Furthermore, various effects directly or indirectly identified through the present specification may be provided.

The above description is merely illustrative of the technical idea of the present disclosure, and those of ordinary skill in the art to which the present disclosure pertains will be able to make various modifications and variations without departing from the essential characteristics of the present disclosure.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The foregoing descriptions of predetermined exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described to explain certain principles of the present disclosure and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A battery diagnostic apparatus comprising:
a storage configured to include battery state history data including periodic battery charge state information;
a battery state manager configured to store the battery state history data in the storage, and to retrieve the stored battery state history data therefrom; and
a battery diagnostic device configured to determine a usage pattern depth of discharge in a state of charge based on the battery state history data, and to predict a remaining life of a battery based on the battery state history data and the usage pattern depth of discharge.

2. The battery diagnostic apparatus of claim 1, wherein the battery state manager is configured to manage the battery state history data to include information on distribution ratios for each section of the state of charge.

3. The battery diagnostic apparatus of claim 2, wherein the battery diagnostic device is configured to determine a sum of the distribution ratios for each section of the state of charge, to determine state of charge sections in which the sum of the distribution ratios is equal to or greater than a threshold ratio as usage patterns, to select a largest state of charge among the usage patterns as a maximum state of charge, to select a smallest state of charge among the usage patterns as a minimum state of charge, and to determine a difference between the maximum state of charge and the minimum state of charge to obtain the usage pattern depth of discharge.

4. The battery diagnostic apparatus of claim 3, wherein the battery diagnostic device is configured to predict the remaining life of the battery to be longer in proportion to a size of the usage pattern depth of discharge.

5. The battery diagnostic apparatus of claim 4, wherein the battery diagnostic device is configured to predict the remaining life of the battery to be longer in proportion to a size of the minimum state of charge.

6. The battery diagnostic apparatus of claim 5, wherein the battery diagnostic device is configured to determine the remaining life of the battery based on Equation 1 below,
$$remaining life of battery ( \% ) = \frac{\begin{matrix}Turn of number [ TON ] - \\ total discharge amount of battery / \\ battery capacity\end{matrix}}{Turn of number [ TON ]} \times 100. \qquad [ Equation 1 ]$$

7. The battery diagnostic apparatus of claim 1, wherein the battery diagnostic device is configured to discharge the battery by driving an electric component receiving a voltage from the battery, to determine a discharge time for which the voltage of the battery reaches a threshold voltage due to the discharge of the battery, and to determine that as the discharge time is shorter, a possibility of battery failure is higher.

8. The battery diagnostic apparatus of claim 7, wherein the battery diagnostic device is configured to discharge the battery by driving the electric component in a state in which an operation of a low voltage DC-DC converter reducing a high voltage and providing a voltage to the battery is stopped.

9. The battery diagnostic apparatus of claim 7, wherein the battery diagnostic device is configured to allow the battery to be discharged by driving the electric component based on the state of charge of the battery of 50% or more than 50%.

10. The battery diagnostic apparatus of claim 9, wherein the battery diagnostic device is configured to notify a user of a recommendation to replace the battery based on a fact that the discharge time is less than a threshold time.

11. A battery diagnostic method comprising:
retrieving battery state history data including periodic battery charge state information;
determining a usage pattern depth of discharge of a state of charge based on the battery state history data; and
predicting a remaining life of a battery based on the battery state history data and the usage pattern depth of discharge.

12. The battery diagnostic method of claim 11, wherein the retrieving of the battery state history data includes extracting distribution ratios of the state of charge for each section from the battery state history data.

13. The battery diagnostic method of claim 12, wherein the determining of the usage pattern depth of discharge includes:
determining a sum of the distribution ratios for each section of the state of charge;
determining state of charge sections in which the sum of the distribution ratios is equal to or greater than a threshold ratio as usage patterns;
selecting a largest state of charge among the usage patterns as a maximum state of charge;
selecting a smallest state of charge among the usage patterns as a minimum state of charge; and
determining a difference between the maximum state of charge and the minimum state of charge to obtain the usage pattern depth of discharge.

14. The battery diagnostic method of claim 13, wherein the predicting of the remaining life of the battery includes predicting the remaining life of the battery to be longer in proportion to a size of the usage pattern depth of discharge.

15. The battery diagnostic method of claim 14, wherein the predicting of the remaining life of the battery includes predicting the remaining life of the battery to be longer in proportion to a size of the minimum state of charge.

16. The battery diagnostic method of claim 15, wherein the predicting of the remaining life of the battery includes determining the remaining life of the battery based on Equation 1 below,
$$remaining life of battery ( \% ) = \frac{\begin{matrix}Turn of number [ TON ] - \\ total discharge amount of battery / \\ battery capacity\end{matrix}}{Turn of number [ TON ]} \times 100. \qquad [ Equation 1 ]$$

16. The battery diagnostic method of claim 11, further including:
after the predicting of the remaining life of the battery,
discharging the battery by driving an electric component receiving a voltage from the battery;
determining a discharge time for which the voltage of the battery reaches a threshold voltage due to the discharge of the battery; and
determining that as the discharge time is shorter, a possibility of battery failure is higher.

18. The battery diagnostic method of claim 17, wherein the discharging the battery by driving the electric component further includes stopping an operation of an low voltage DC-DC converter that reduces a high voltage and provides a voltage to the battery.

19. The battery diagnostic method of claim 17, wherein the allowing of the battery to be discharged by driving the electric component is performed based on confirming that the state of charge of the battery is 50% or more than 50%.

20. The battery diagnostic method of claim 19, further including:
notifying a user of a recommendation to replace the battery based on a fact that the discharge time is less than a threshold time.
